(19) United States
(12) Patent Application Publication
(10) Pub. No.: US 2016/0071722 A1
(43) Pub. Date: Mar. 10, 2016

(54) PLASMA PROCESSING DEVICE AND PLASMA PROCESSING METHOD

(71) Applicant: Tokyo Electron Limited, Tokyo (JP)

(72) Inventors: Shigehiro MIURA, Iwate (JP); Jun SATO, Iwate (JP)

(21) Appl. No.: 14/840,250

(22) Filed: Aug. 31, 2015

(30) Foreign Application Priority Data
Sep. 9, 2014 (JP) 2014-183609

(51) Int. Cl. H01L 21/02; H01L 21/311; H01L 21/687; H01J 37/32; H01L 21/67; C23C 16/455; C23C 16/458

(52) U.S. Cl. CPC H01L 21/0234; C23C 16/45544; C23C 16/45536; H01L 21/31116; C23C 16/4584; H01J 37/32458; H01J 37/32715; H01L 21/67069; H01L 21/68764; H01J 2237/332; H01J 2237/334

(57) ABSTRACT

A plasma processing apparatus includes a processing chamber. A turntable to receive a substrate thereon is provided in the processing chamber. A first plasma processing area is provided in a predetermined location in a circumferential direction of the turntable and configured to perform a first plasma process by generating first plasma from a first plasma gas. A second plasma processing area is provided apart from the first plasma processing area in the circumferential direction of the turntable and configured to perform a second plasma process by generating second plasma from a second plasma gas. A separation area is provided in each of two locations between the first plasma processing area and the second plasma processing area and configured to prevent the first plasma gas and the second plasma gas from mixing with each other by separating the first plasma processing area from the second plasma processing area.

### CROSS-REFERENCE TO RELATED APPLICATION

The present application is based upon and claims the benefit of priority of Japanese Patent Application No. 2014-183609, filed on Sep. 9, 2014, the entire contents of which are incorporated herein by reference.

### BACKGROUND OF THE INVENTION

1. Field of the Invention

The present invention relates to a plasma processing apparatus and a plasma processing method.

2. Description of the Related Art

Conventionally, as disclosed in Japanese Patent Application Publication No. 2010-56470, a variety of films constituting semiconductor devices is demanded to be thinner and more uniform with miniaturization of circuit patterns in the semiconductor devices. What is called MLD (Molecular Layer Deposition) or ALD (Atomic Layer Deposition) is known as a film deposition method for responding to the demand. In the method, a first reaction gas is absorbed on a surface of a substrate by supplying the first reaction gas to the substrate, and then the first gas adsorbed on the surface of the substrate is caused to react with a second reaction gas by supplying the second reaction gas to the substrate, thereby depositing a film composed of a reaction product of the first reaction gas and the second reaction gas on the substrate. According to such a method of depositing a firm, because the reaction gas can adsorb on the surface of the substrate in a (quasi-)self-saturation manner, high film thickness controllability, excellent uniformity, and excellent filling characteristics can be achieved.

However, with the miniaturization of circuit patterns, for example, filling a trench and a space is sometimes difficult even in the molecular layer deposition method with the increasing aspect ratio of the trench in a trench device separation structure or of a space in a line-and-space pattern. For example, when trying to fill the space having a width of about 30 nm with a silicon oxide film, because the reaction gas is difficult to go to a bottom part of a narrow space, the film becomes thick in the vicinity of the upper end of a side wall of the line that partitions the space and becomes thin on the bottom part side. This sometimes causes a void to be generated in the silicon oxide film filling the space. For example, when such a silicon oxide film is etched in a subsequent etching process, an opening in communication with the void is sometimes formed in an upper surface of the silicon oxide film. On this occasion, contamination is liable to occur by allowing an etching gas (or an etching solution) to go into the void from the opening, or a defect is liable to occur by allowing metal to go into the void in a subsequent metallization process.

Such a problem can occur in CVD (Chemical vapor Deposition) without being limited to ALD. For example, when forming a conductive contact hole (so-called a plug) by filling a contact hole formed in a semiconductor substrate with a conductive material, a void may be generated in the plug. As disclosed in Japanese Patent Application Publication No. 2003-142484, to prevent this, a method is proposed of forming a conductive contact hole in which a void is reduced by repeating a step of removing overhangs projecting toward the center of the contact hole of the conductive material formed in the upper part or on the top of the contact hole when filling the contact hole with the conductive material by an etch back process.

However, in the etching process used in filling the above-mentioned space and contact hole with the conductive material, an improvement in film quality after the etching process is not always enough, and there has been a concern about a residue of a fluoride component of a fluoride-containing gas used in the etching process, which has been liable to decrease the film quality.

### SUMMARY OF THE INVENTION

In view of the above, embodiments of the present invention aims to provide a plasma processing apparatus and a plasma processing method that can reduce a fluoride concentration in a film.

In an embodiment of the present invention, there is provided a plasma processing apparatus that includes a processing chamber. A turntable to receive a substrate thereon is provided in the processing chamber.

A first plasma processing area is provided in a predetermined location in a circumferential direction of the turntable and configured to perform a first plasma process by generating first plasma from a first plasma gas. A second plasma processing area is provided apart from the first plasma processing area in the circumferential direction of the turntable and configured to perform a second plasma process by generating second plasma from a second plasma gas. A separation area is provided in each of two locations between the first plasma processing area and the second plasma processing area and configured to prevent the first plasma gas and the second plasma gas from mixing with each other by separating the first plasma processing area from the second plasma processing area.

In another embodiment of the present invention, there is provided a plasma processing method. In the method, a first plasma process is performed on a substrate by generating first plasma from a first plasma gas. The substrate subject to the first plasma process is purged by a purge gas. A second plasma process is performed on the purged substrate by generating second plasma from a second plasma gas. The substrate subject to the second plasma process is purged by a purge gas. Two types of plasma processes constituted of the first plasma process and the second plasma process alternately are performed by repeating a cycle constituted of steps of performing the first plasma, purging the substrate subject to the first plasma process, performing the second plasma process and purging the substrate subject to the second plasma process a plurality of times in a constant period.

Additional objects and advantages of the embodiments are set forth in part in the description which follows, and in part will become obvious from the description, or may be learned by practice of the invention. The objects and advantages of the invention will be realized and attained by means of the elements and combinations particularly pointed out in the appended claims. It is to be understood that both the foregoing general description and the following detailed description are exemplary and explanatory and are not restrictive of the invention as claimed.

### BRIEF DESCRIPTION OF THE DRAWINGS

FIG. 1 is a vertical cross-sectional view illustrating an example of a plasma processing apparatus according to an embodiment of the present invention;

FIG. 2 is a horizontal cross-sectional view illustrating an example of the plasma processing apparatus according to an embodiment of the present invention;

FIG. 3 is a horizontal cross-sectional view illustrating an example of the plasma processing apparatus according to an embodiment of the present invention;

FIG. 4 is an exploded perspective view illustrating a part of the inside of the plasma processing apparatus according to an embodiment of the present invention is applied;

FIG. 5 is a vertical cross-sectional view illustrating a part of the inside of the plasma processing apparatus according to an embodiment of the present invention;

FIG. 6 is a perspective view illustrating a part of the inside of the plasma processing apparatus according to an embodiment of the present invention;

FIG. 7 is a vertical cross-sectional view illustrating a part of the inside of the plasma processing apparatus according to an embodiment of the present invention;

FIG. 8 is a plan view illustrating a part of the inside of the plasma processing apparatus according to an embodiment of the present invention;

FIG. 9 is a perspective view illustrating a Faraday shield of the plasma processing apparatus according to an embodiment of the present invention;

FIG. 10 is a perspective view illustrating a part of the Faraday shield of the plasma processing apparatus according to an embodiment of the present invention;

FIGS. 11A through 11D are process drawings illustrating an example of a plasma processing method according to an embodiment of the present invention;

FIGS. 12A and 12B are a series of process drawings for explaining a modification process of the plasma processing method according to an embodiment of the present invention;

FIG. 13 is a graph showing a result of analysis of a fluoride concentration in a SiO₂ film after performing a conventional modification process;

FIGS. 14A and 14B are diagrams showing simulation results indicating a separation state of hydrogen gas in the plasma processing apparatus according to an embodiment of the present invention;

FIGS. 15A and 15B are diagrams showing simulation results indicating a separation state of NF₃ gas in the plasma processing apparatus according to an embodiment of the present invention;

FIGS. 16A and 16B are diagrams showing simulation results indicating separation characteristics of a separation gas in terms of pressure of the plasma processing apparatus according to an embodiment of the present invention; and

FIGS. 17A and 17B are diagrams showing simulation results indicating separation characteristics of a separation gas in terms of mass concentration of the plasma processing apparatus according to an embodiment of the present invention.

### DESCRIPTION OF THE PREFERRED EMBODIMENTS

A description is given below of embodiments of the present invention with reference to the accompanying drawings.

To begin with, a description is given below of an example of an etching apparatus to which a plasma processing apparatus and a plasma processing method according to an embodiment of the present invention are applied. The plasma processing apparatus and the plasma processing method according to an embodiment of the present invention are applicable not only to an etching apparatus, but also to all kinds of apparatuses that perform a plasma process such as a film deposition apparatus and a substrate processing apparatus that performs both of the etching and the film deposition. However, in the embodiment, a description is given below of an example in which a plasma processing apparatus according to an embodiment of the present invention is configured as an etching apparatus.

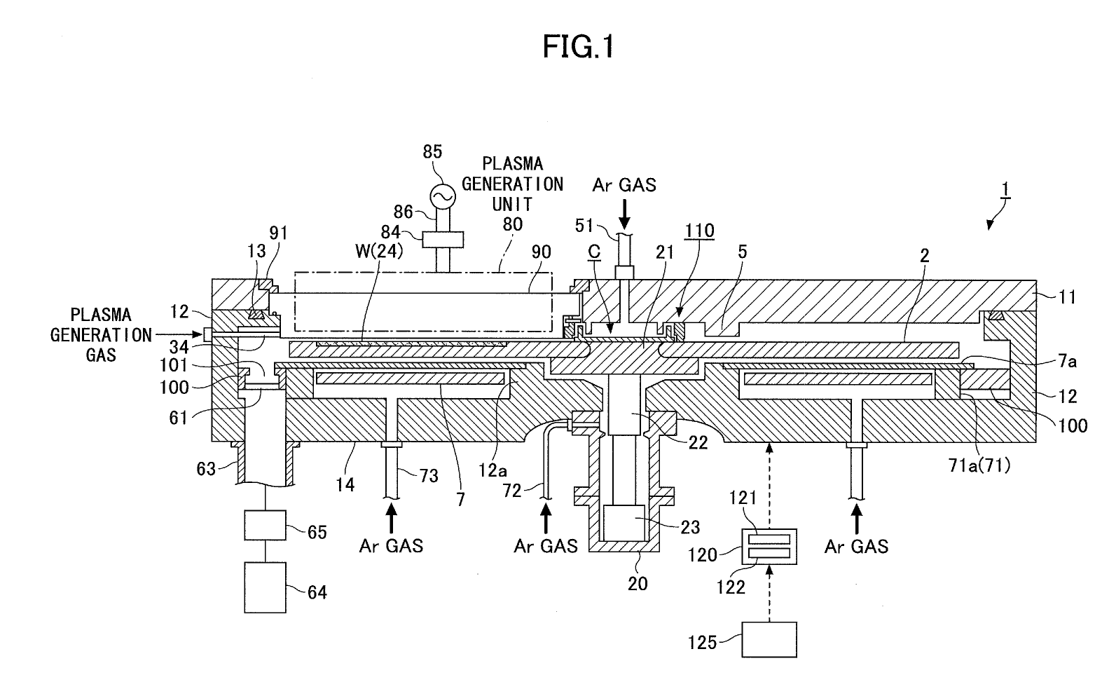

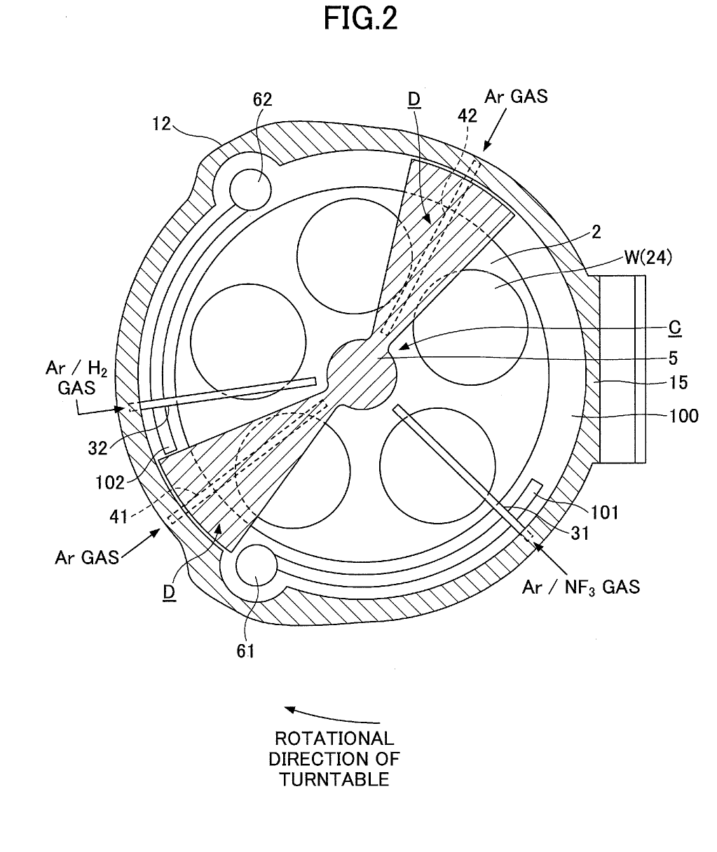

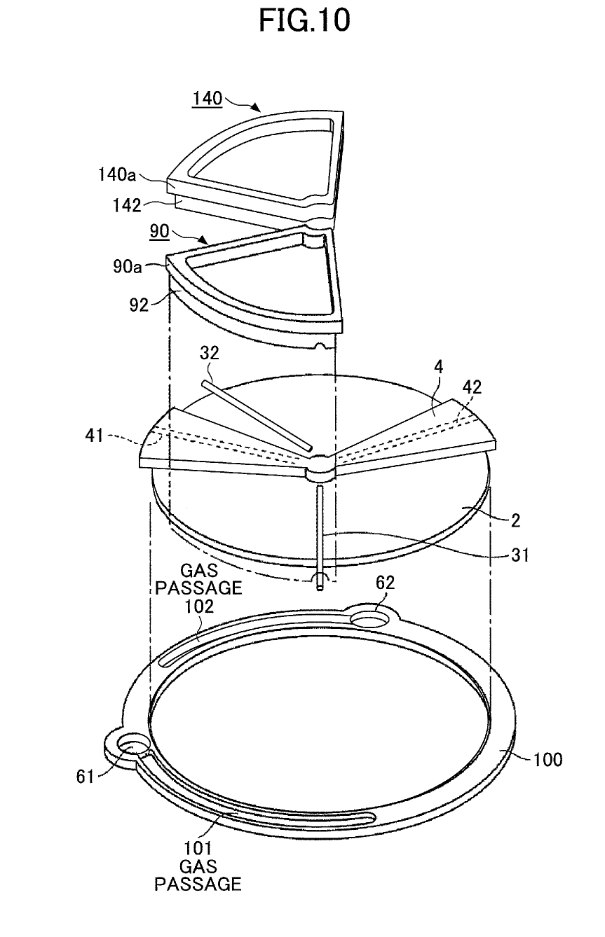

A description is given of an example of an etching apparatus to which a plasma processing apparatus of the embodiment of the present invention is applied, with reference to FIGS. 1 through 10. As illustrated in FIGS. 1 and 2, the etching apparatus of the embodiment includes a processing chamber 1 having a substantially circular planar shape, and a turntable 2 provided inside the processing chamber 1, which has a rotational center positioned at the center of the processing chamber 1. Furthermore, as described in detail below, the etching apparatus is configured to etch a thin film deposited on a surface of a wafer W by ALE (Atomic Layer Etching) and to perform a plasma modification on the thin film after the etching. At this time, to perform the plasma modification, the etching apparatus is configured so that the thin film does not contain a fluoride component or contains the fluoride component as little as possible by removing the fluoride component contained in the thin film by plasma. More specifically, the etching is often performed by using a fluoride-containing etching gas in a semiconductor process, and when the fluoride component remains in a film that is an etching object, a device property becomes worse. In particular, when the fluoride component remains in a silicon-based film such as SiO₂, SiN and the like, the remaining fluoride component adversely affects the device property. In the meantime, as discussed above, because the fluoride-containing gas such as NF₃ or the like is often used as the etching gas, when etching a film, a fluoride concentration in the film generally increases, and decreasing the fluoride concentration as little as possible is a technical problem. Hence, the etching apparatus of the embodiment performs a periodical small quantity of etching and effectively removes the fluoride component remaining in the film by a periodical modification process, but details of this point will be described later. Subsequently, a detailed description is given below of each part of the etching apparatus.

The processing chamber 1 includes a ceiling plate 11 and a chamber body 12, and the ceiling plate 11 is detachable from the chamber body 12. At the center part on the top surface side of the ceiling plate 11, a separation gas supply tube 51 is connected thereto for supplying Ar gas as a separation gas, for preventing different types of processing gases from mixing with each other, at a central area C in the processing chamber 1. Furthermore, FIG. 1 illustrates a seal member 13 (for example, an O-ring) provided in a ring shape along the outer peripheral part of the top surface of the chamber body 12.

The center part of the turntable 2 is fixed to a core part 21 having a substantially cylindrical shape. The turntable 2 is rotatable around a vertical axis (in a clockwise direction in this example), by a rotary shaft 22, which is connected to the bottom surface of the core part 21 and which extends in the vertical direction. A driving unit 23 is a driver that rotates the rotary shaft 22 around the vertical axis. A case body 20 accommodates the rotary shaft 22 and the driving unit 23. A flange part of the top surface of this case body 20 is attached to the bottom side of a bottom part 14 of the processing chamber 1 in a gastight manner. Furthermore, a purge gas supply tube 72 is connected to an area below the turntable 2 of the case body 20, for supplying Ar gas as a purge gas. In the processing chamber 1, at the part of the bottom part 14 at the outer peripheral side of the core part 21, a ring shape is formed adjacent to the turntable 2 from below the turntable 2, and the ring shape constitutes a protruding part 12a.

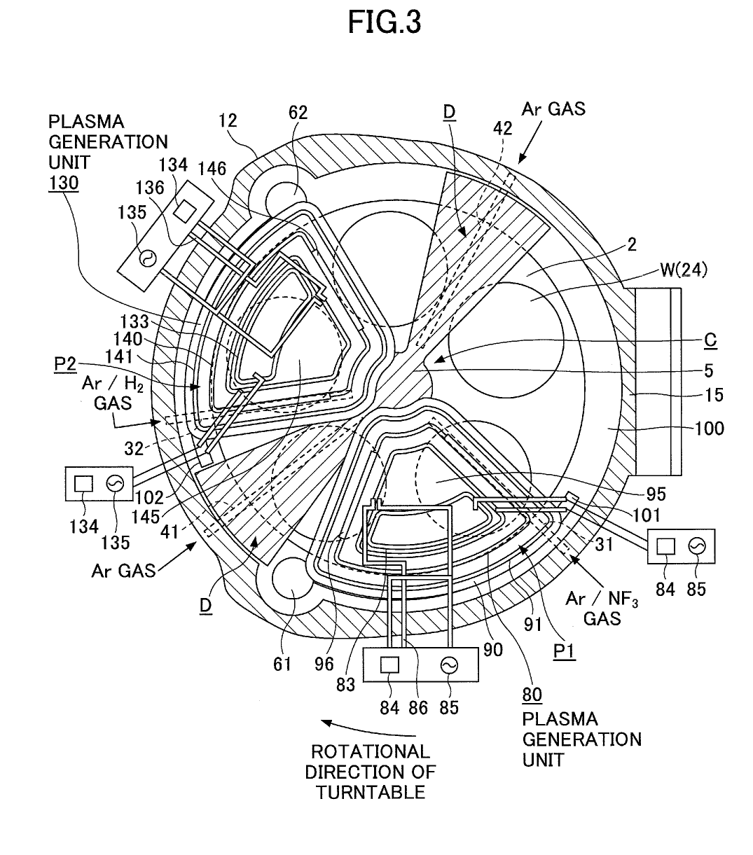

As illustrated in FIGS. 2 and 3, on the surface of the turntable 2, circular recessed portions 24 are provided as substrate receiving areas for receiving wafers W thereon which are a plurality of (for example, five) substrates, along the rotational direction (circumferential direction). The diameter and the depth of the recessed portions 24 are set such that when wafers W having a diameter of, for example, 300 mm, are placed on the recessed portions 24, the surface of the wafer W and the surface of the turntable 2 (areas where the wafers W are not placed) are flat. At the bottom of the recessed portions 24, through holes (not illustrated in the drawings) are formed to allow a plurality of (e.g., three) lift pins to penetrate therethrough in order to raise the wafer W from below and to move the wafer W up and down.

As illustrated in FIGS. 2 and 3, four nozzles 31, 32, 41 and 42 made of, for example, quartz, are radially arranged at positions above the turntable 2 facing the recessed portions 24. The nozzles 31, 32, 41 and 42 are arranged interposing gaps in the circumferential direction (a rotational direction of the turntable 2) of the processing chamber 1. For example, each of the nozzles 31, 32, 41 and 42 is attached so as to extend horizontally facing the wafer W from the outer peripheral wall of the processing chamber 1 toward the central area C. In this example, a first plasma gas nozzle 31, a separation gas nozzle 41, a second plasma gas nozzle 32, and a separation gas nozzle 42 are arranged in this order in a clockwise fashion (rotational direction of turntable 2) as viewed from a transfer opening 15 described below. As illustrated in FIG. 1, above the first plasma gas nozzle 31, a first plasma generation unit 80 is provided to convert a gas discharged from the first plasma gas nozzle 31 into plasma. Moreover, above the second plasma gas nozzle 32, a second plasma generation unit 130 is provided to convert a gas discharged from the second plasma gas nozzle 32 into plasma. In FIG. 1, the second plasma generation unit 130 is not depicted.

Details of the first and second plasma generation units 80 and 130 are described later.

The plasma gas nozzles 31 and 32 constitute a first plasma gas supply unit and a second plasma gas supply unit, respectively. The separation gas nozzles 41 and 42 constitute separation gas supply units, respectively. Note that FIG. 2 illustrates a state in which the plasma generation unit 80 and a case 90 that will be described later have been removed such that the plasma gas nozzles 31 and 32 can be seen, and FIG. 3 illustrates a state in which the plasma generation units 80 and 130 and cases 90 and 140 are attached. Furthermore, in FIG. 1, the plasma generation unit 80 is schematically illustrated by a dashed-dotted line (the plasma generation unit 130 is not illustrated in FIG. 1).

Each of the nozzles 31, 32, 41 and 42 is connected to a gas supply source (not illustrated in the drawings) described below, through a flow rate adjustment valve. That is to say, the first plasma gas nozzle 31 is connected to a supply source of an etching gas, and for example, a fluoride-containing gas such as NH₃ gas or the like is used as the etching gas. The second plasma gas nozzle 32 is connected to a supply source of a modification gas, and for example, hydrogen gas and the like are used as the modification gas because hydrogen gas can react with fluoride and remove fluoride from a film by becoming HF and escaping from the film together with fluoride. The first plasma gas nozzle 31 is connected to a supply source of mixed gas of, for example, Ar (argon) gas and NF₃ gas. Each of the separation gas nozzles 41 and 42 is connected to a gas supply source of an inactive gas (including a noble gas) such as Ar gas, N₂ gas or the like that is the separation gas. As a matter of convenience, a description is given below of an example in which the film to be etched is a SiN film; the etching gas supplied from the first plasma gas nozzle 31 is a mixed gas of Ar and NF₃; the modification gas supplied from the second plasma gas nozzle 32 is a mixed gas of Ar and H₂; and the separation gas is Ar gas. Although N₂ gas may be used as the separation gas when the film to be etched is a SiN film, Ar gas is preferred to be used as the separation gas when the film to be etched is the SiO₂ film so as not to produce SiON and the like. Hereinafter, the etching gas supplied from the first plasma gas nozzle 31 may be referred to as a first plasma gas, and the modification gas supplied from the second plasma gas nozzle 32 may be referred to as a second plasma gas.

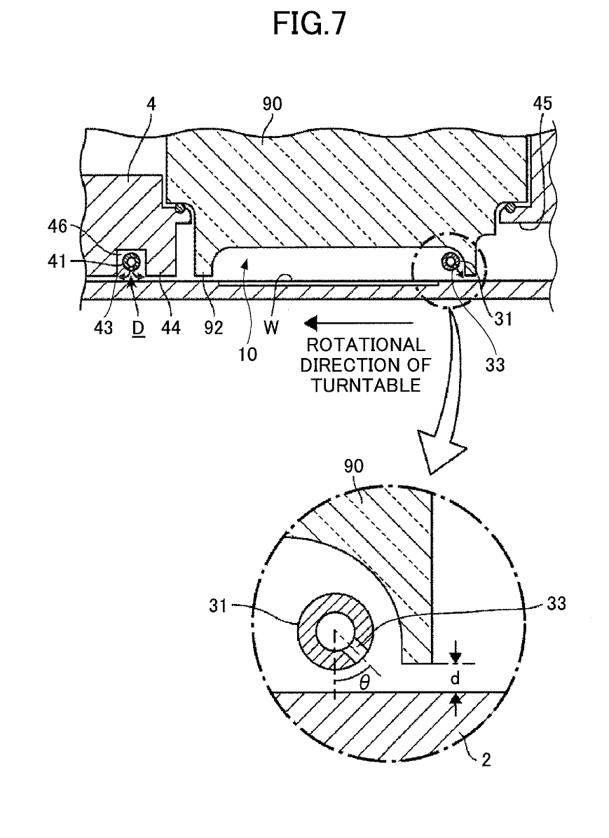

As illustrated in FIG. 7, gas discharge holes 33 and 43 are formed in lower surfaces of the plasma gas nozzles 31 and 32, and the separation gas nozzles 41 and 42, respectively, at a plurality of positions along the radial direction of the turntable 2, for example, at regular intervals. More specifically, the gas discharge holes 33 having a diameter of, for example, 0.3 mm through 0.5 mm, are formed in a lower lateral surface of the plasma gas nozzle 31, at a plurality of positions along the longitudinal direction of the plasma gas nozzle 33, for example, at regular intervals, so as to face the upstream side in the rotation direction (on the side of the second processing gas nozzle 32) and the bottom side (obliquely downward) of the turntable 2. The reason of setting the direction of the gas discharge holes 33 of the plasma gas nozzle 31 as described above is described below. These nozzles 31, 32, 41 and 42 are arranged such that the distance between the bottom edge of the nozzles 31, 32, 41 and 42 and the top surface of the turntable 2 is, for example, approximately 1 mm through 5 mm.

Areas below the first and second plasma gas nozzles 31 and 32 are referred to as a first plasma processing area P1 where the SiO₂ film deposited on the wafer W is to be etched, and a second plasma processing area P2 where the surface of the etched SiO₂ film is to be modified, respectively. The separation gas nozzles 41 and 42 are for forming separation areas D that separate the first plasma processing area P1 from the second plasma processing area P2. As illustrated in FIGS. 2 and 3, convex portions 4 having a substantially sector shape, are provided on the ceiling plate 11 of the processing chamber 1 in the separation areas D, and the separation gas nozzles 41 and 42 are accommodated in grooves 46 that are formed in the convex portions 4. Therefore, on both sides of each of the separation gas nozzles 41 and 42 in the circumferential direction of the turntable 2, there are provided low ceiling surfaces 44 (first ceiling surfaces) that correspond to the bottom surfaces of the convex portions 4, in order to prevent the different types of processing gases from being mixed with each other. On both sides of the ceiling surfaces 44 in the circumferential direction, there are provided ceiling surfaces 45 (second ceiling surfaces) that are lower than the ceiling surfaces 44. The outer peripheral parts (the outer edge side of the processing chamber 1) of the convex portions 4 form bent portions which are bent into an L shape so as to face the outer edge surface of the turntable 2 and to be slightly spaced apart from the chamber body 12, in order to prevent the different types of processing gases from being mixed with each other.

As illustrated in FIGS. 2 and 3, the separation areas D are provided in two distant spaces between the first plasma processing area P1 in which the etching process is performed and the second plasma processing area P2 in which the modification process is performed. Hence, the first plasma processing area P1 is reliably separated from the second plasma processing area P2 by way of the separation areas D. For example, when (Ar+NF₃) gas is supplied from the first plasma gas nozzle 31 provided in the first plasma processing area P1 and (Ar+H₂) gas is supplied from the second plasma processing gas nozzle 32 provided in the second plasma processing area P2, and if NF₃ gas and H₂ gas mix with each other in a predetermined concentration range (1.5 to 90.6%), an explosion is liable to occur. Accordingly, to reliably prevent the mixture of NF₃ gas and H₂ gas, the separation areas D are provided in two of the distant spaces between the first plasma processing area P1 and the second plasma processing area P2, respectively, thereby reliably preventing NF₃ gas supplied into the first plasma processing area P1 and H₂ gas supplied into the second plasma processing area P2 from mixing with each other.

More specifically, NF₃ gas and H₂ gas react with each other by the following chemical formula (1).

3H₂+2NF₃→6HF+N₂ (1)

Here, when H₂ gas and NF₃ gas are in a predetermined concentration range, the explosion is liable to occur as described above, but even if the explosion does not occur, HF is produced as a result of the reaction. Because HF is a corrosive gas, when HF gas is generated and attaches to the inner wall and the like of the processing chamber 1, HF gas is liable to corrode the attached portion such as the inner wall. Hence, even if the explosion does not occur, the plasma processing apparatus is preferred to have a structure that prevents NF₃ gas and H₂ gas from mixing with each other. On this point, because the plasma processing apparatus of the embodiment includes the separation areas D that separate the first plasma processing area P1 from the second plasma processing area P2 by the convex portions 4 and the supply of the separation gas (Ar gas), the explosion and the internal corrosion of the processing chamber 1 can be reliably prevented.

The separation areas D may be referred to as purge areas D, and the separation gas may be referred to as a purge gas because the separation gas plays a role equivalent to the purge gas.

In addition, although the first and second plasma processing areas P1 and P2 have a structure that prevents a gas from going into the first and second plasma processing areas P1 and P2 from the outside, respectively, a description is given later on this point.

The first and second plasma gas nozzles 31 and 32 are both provided at positions on the upstream side of the first and second plasma processing area, respectively. This is intended to promptly convert NF₃ gas and H₂ gas supplied from the first and second plasma gas nozzles 31 and 32, respectively, into plasma and to reliably perform the plasma process while the wafer W passes the first and second plasma processing areas P1 and P2.

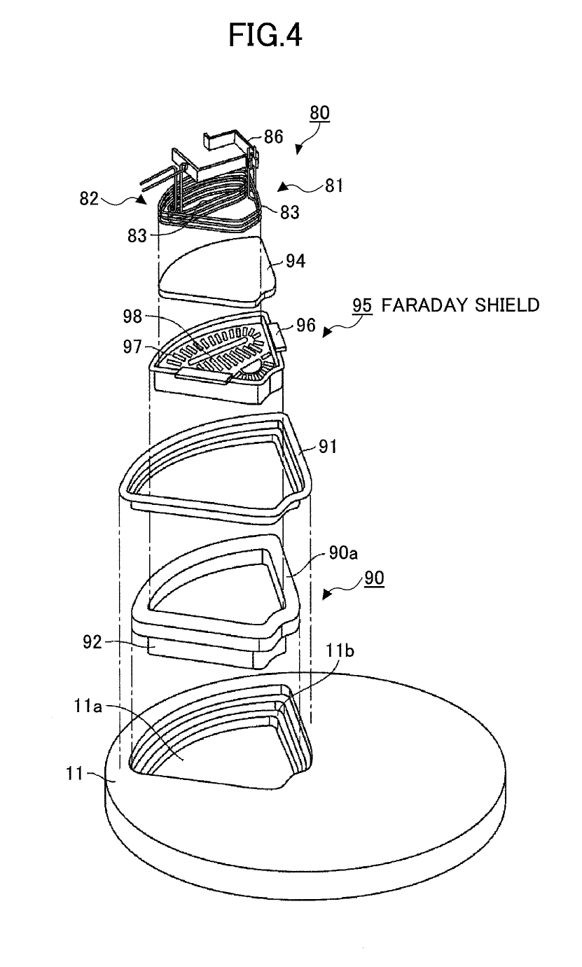

Next, a detailed description is given of the plasma generation unit 80. The plasma generation unit 80 is configured by winding around an electrode 83 (or may be referred to as an “antenna”) to form a coil, which is constituted by a metal wire such as copper (Cu) or the like. The plasma generation unit 80 is provided on the ceiling plate 11 of the processing chamber 1 so as to be partitioned from the inside area of the processing chamber 1 in a gastight manner. In this example, the electrode 83 is made of a material formed by applying a nickel coating and gold coating on a copper surface in this order. More specifically, as illustrated in FIG. 4, an opening 11a that is open in a substantially sector shape in a planar view is formed in the ceiling plate 11 above the plasma gas nozzle 31 (specifically, from a position that is slightly on the upstream side in the rotational direction of the turntable 2 with respect to the plasma gas nozzle 31, to a position that is slightly closer to the plasma gas nozzle 31 than the separation area D on the downstream side in the rotational direction of the plasma gas nozzle 31).

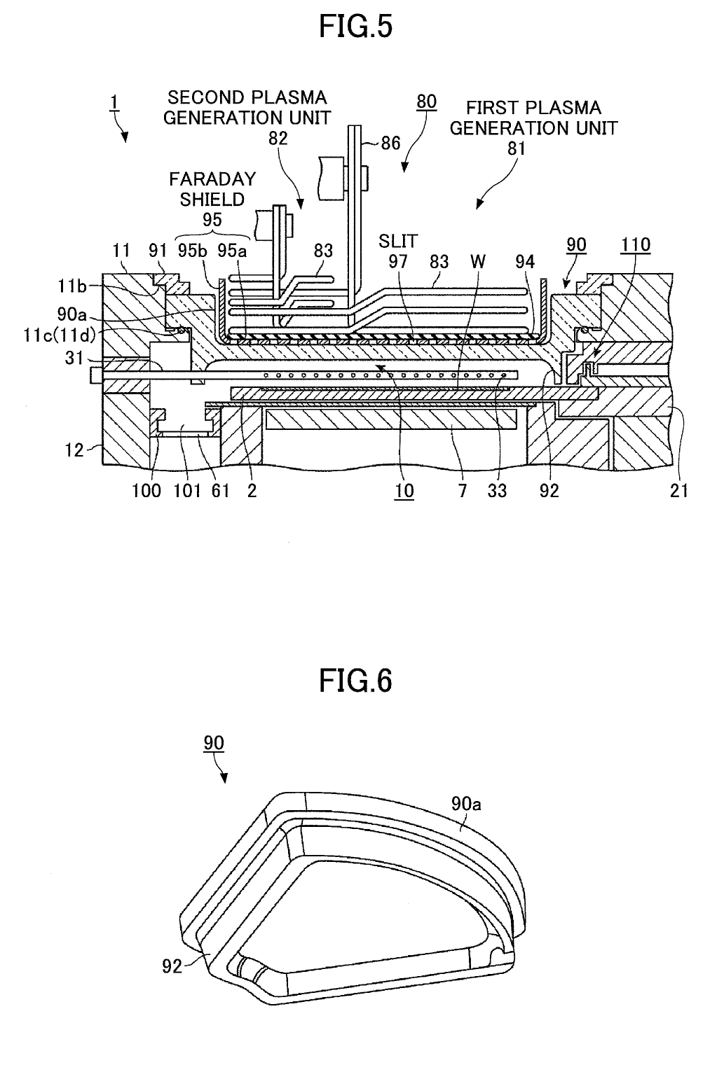

The opening 11a is formed from a position that is spaced apart from the rotational center of the turntable 2 toward the outer peripheral side by, for example, approximately 60 mm, to a position that is spaced apart from the outer edge of the turntable 2 toward the outside by, for example, approximately 80 mm. Furthermore, the edge of the opening 11a on the center side of the turntable 2 in a planar view is hollowed into an arc shape along the outer edge of a labyrinth structure part 110, so as not to interfere with (to avoid) the labyrinth structure part 110 (described below) provided at the central area C of the processing chamber 1. Furthermore, as illustrated in FIGS. 4 and 5, in the opening 11a, for example, three stage parts 11b are formed in the circumferential direction, such that the diameter of the opening 11a is gradually reduced from the top side of the ceiling plate 11 toward the bottom side of the ceiling plate 11. On the top surface of the lowest one of the stage parts 11b (rim part), there is formed a groove 11c in the circumferential direction as illustrated in FIG. 5. A seal member, for example, an O-ring lid is arranged in the groove 11c. Note that the groove 11c and the O-ring 11d are not illustrated in FIG. 4.

In the opening 11a, as illustrated in FIG. 6, the case 90 is arranged. In the case 90, the outer peripheral part on the top side extends out horizontally along the circumferential direction in a flange shape forming a flange part 90a. Furthermore, the center part of the case 90 is formed so as to be hollowed toward the inside area of the processing chamber 1 below the case 90. This case 90 is constituted by a magnetically permeable body (a material through which magnetic force is permeated), made of a dielectric material such as quartz, in which the thickness t of the hollowed part is, for example, 20 mm as illustrated in FIG. 9. Furthermore, when the wafer W is positioned at the bottom of the case 90, on the central area C side, the distance between the inner wall surface of the case 90 and the edge of the wafer W is 70 mm, and on outer peripheral side of the turntable 2, the distance between the inner wall surface of the case 90 and the outer edge of the wafer W is 70 mm. Thus, the angle α formed by the two sides of the opening 11a at the upstream side and the downstream side in the rotational direction of the turntable 2 and the rotational center of the turntable 2 is, for example, 68°.

The case 90 is made of a material having a high anti-plasma etching property such as high purity quartz, high purity alumina, and yttria. Otherwise, at least the surface layer part of the case 90 is coated by this material. Thus, the case 90 is basically made of a dielectric material.

When the case 90 is fitted in the opening 11a, the flange part 90a is engaged with the bottommost stage part 11b. Then, the stage parts 11b (ceiling plate 11) and the case 90 are connected in a gastight manner by the O-ring 11d. Furthermore, while the flange part 90a is pressed downward along the circumferential direction by a suppressing member 91, which is formed to have a frame-like shape extending along the outer edge of the opening 11a, the suppressing member 91 is fixed to the ceiling plate 11 by a bolt (not illustrated in the drawings), thereby setting the internal atmosphere of the processing chamber 1 in a gastight state. When the case 90 is fixed to the ceiling plate 11 in a gastight manner as described above, the distance h between the bottom surface of the case 90 and the surface of the wafer W on the turntable 2 is set at 4 mm through 60 mm (30 mm in this example). Note that FIG. 6 is a view from the bottom of the case 90.

As illustrated in FIGS. 1 and 5 through 7, in order to prevent N₂ gas and O₃ gas from entering an area under the case 90, a projection part 92 for regulating a gas is formed on the bottom surface of the case 90. More specifically, the outer edge of the case 90 vertically extends out downward (toward the turntable 2) along the circumferential direction, thereby forming the projection part 92. The plasma gas nozzle 31 is accommodated, on the upstream side in the rotational direction of the turntable 2, in the area that is surrounded by the inner peripheral surface of the projection part 92, the bottom surface of the case 90, and the top surface of the turntable 2.

Here, the projection part 92 is formed on the lower surface side of the case 90 so as to prevent a gas from going into the area under the case 90 (plasma space 10) from the outside. As discussed above, because the first plasma processing area 21 is separated from the second plasma processing area P2 by the separation areas D that separate the first plasma processing area P1 from the second plasma processing area P2 by supplying Ar gas, a space between the separation area D and the first plasma processing area P1 is filled with Ar gas, but when Ar gas from the outside enters the first plasma processing area P1, the concentration of NF₃ gas decreases. Therefore, to prevent Ar gas from entering the area under the case 90, the projection part 92 is formed in the lower surface of the case 90.

In addition, when the film to be etched is a SiN film, N₂ gas is sometimes used as the separation gas. In this case, because the gas supplied from the plasma gas nozzle 31 is converted into plasma in the area under the case 90 (plasma space 10), when N₂ gas enters the plasma space 10, plasma of N₂ gas and plasma of O₃ gas (O₂ gas) react with each other and NOx gas is generated. When NOx gas is generated, the members in the processing chamber 1 are corroded. Therefore, in order to reduce N₂ gas entering the area under the case 90, the projection part 92 is formed in the lower surface of the case 90.

The projection part 92 on the base end side of the plasma gas nozzle 31 (on the lateral wall side of the processing chamber 1) is cut out into a substantially arc shape along the external shape of the plasma gas nozzle 31. The distance d (see FIG. 7) between the bottom surface of the projection part 92 and the top surface of the turntable 2 is 0.5 mm through 4 mm (2 mm in this example). The width and the height of the projection part 92 are set at, for example, 10 mm and 28 mm, respectively. Note that FIG. 7 is a cross-sectional view of the processing chamber 1 cut along the rotational direction of the turntable 2.

Furthermore, during the etching process, the turntable 2 rotates in a clockwise fashion, and therefore, along with the rotation of the turntable 2, N₂ gas tends to enter the bottom side of the case 90 through a gap between the turntable 2 and the projection part 92. Therefore, in order to prevent N₂ gas from entering the bottom side of the case 90 through this gap, a gas is discharged from the bottom side of the case 90 to the gap. More specifically, as illustrated in FIGS. 5 and 7, the gas discharge holes 33 of the plasma gas nozzle 31 are arranged so as to face toward the gap, i.e., the gas discharge holes 33 are arranged on the upstream side in the rotational direction of the turntable 2 and are arranged to face downward. For example, the angle θ of the direction of the gas discharge holes 33 of the plasma gas nozzle 31 with respect to the vertical axis is approximately set at 45° as illustrated in FIG. 7.

Here, referring to the O-ring 11d sealing the area between the ceiling plate 11 and the case 90 from below the case 90 (plasma space 10), as illustrated in FIG. 5, the projection part 92 is formed in the circumferential direction between the plasma space 10 and the O-ring 11d. Hence, to prevent the O-ring 11d from being directly exposed to plasma, the O-ring 11d is isolated from the plasma space 10. Accordingly, for example, even if the plasma in the plasma space 10 is likely to diffuse toward the O-ring 11d, because the plasma passes through the part below the projection part 92, the plasma is likely to become inactivated before reaching the O-ring 11d.

A grounded Faraday shield 95, which is formed to substantially extend along the inner shape of the case 90, is accommodated inside the case 90 (in the area that is caved in downwards in the case 90). The grounded Faraday shield 95 is formed of a metal plate that is made of a conductive plate-like body having a thickness k of, for example, approximately 1 mm. In this example, the Faraday shield 95 is made of a plate material that is a copper (Cu) plate or a plate material formed by coating a copper plate with a nickel (Ni) film or a gold (Au) film from below. That is to say, the Faraday shield 95 includes a horizontal surface 95a that is formed horizontally along the bottom surface of the case 90, and a vertical surface 95b extending upward along the circumferential direction from the outer peripheral edge of the horizontal surface 95a, and is formed to have a substantially sector-like shape along the inner edge of the case 90 as viewed from above. The Faraday shield 95 is formed by, for example, performing a rolling process on a metal plate, or by bending upward the area of the metal plate corresponding to an area outside the horizontal surface 95a.

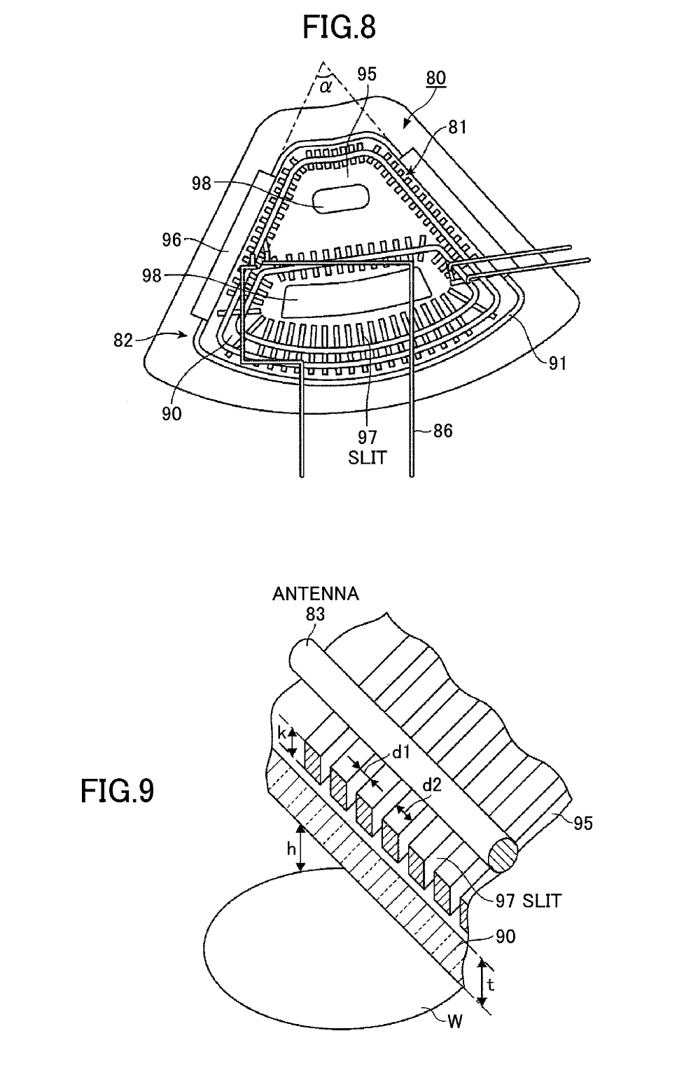

Furthermore, the upper edges of the Faraday shield 95 on the right side and the left side as viewed from the rotational center of the turntable 2, respectively horizontally extend toward the right side and the left side, thereby forming support parts 96. Furthermore, when the Faraday shield 95 is accommodated inside the case 90, the bottom surface of the Faraday shield 95 and the top surface of the case 90 contact each other, and the support parts 96 are supported by the flange part 90a of the case 90. On top of the horizontal surface 95a, in order to insulate the Faraday shield 95 from the plasma generation unit 80 placed on the Faraday shield 95, an insulating plate 94 is laminated, which has a thickness of, for example, approximately 2 mm, and which is made of, for example, quartz. A plurality of slits 97 is formed in the horizontal surface 95a. The shape and the arrangement layout of the slits 97 are described below together with the description of the electrode 83 of the plasma generation unit 80. Note that the insulating plate 94 is not illustrated in FIGS. 8 and 9 described below.

The plasma generation unit 80 is configured to be accommodated inside the Faraday shield 95. Thus, as illustrated in FIGS. 4 and 5, the plasma generation unit 80 is arranged so as to face the inside of the processing chamber 1 (wafer W on the turntable 2), via the case 90, the Faraday shield 95, and the insulating plate 94. The plasma generation unit 80 is configured by winding the electrode 83 around the vertical axis, and the plasma generation unit 80 includes two plasma generation parts 81 and 82 in this example. Each of the plasma generation parts 81 and 82 is formed by winding around the electrode 83 in a triple helix. One of the plasma generation parts 81 and 82 is referred to as first plasma generation part 81 and the other one is referred to as a second plasma generation part 82. As illustrated in FIGS. 4 and 5, the first plasma generation part 81 has a substantially sector-like shape extending along the inner edge of the case 90 in a planar view. Furthermore, the first plasma generation unit 81 is arranged such that the central area C and the outer peripheral edge are in close contact with the inner walls of the case 90, so that it is possible to radiate (supply) plasma along the part between the edge of the wafer W on the central area C side and the outer edge part of the turntable 2, when the wafer W is positioned under the first plasma generation part 81. Note that a flow path through which cooling water flows is formed inside the electrode 83, although not illustrated.

As described above, by adopting a configuration in which the electrode 83 of the plasma generation unit 80 is arranged outside the processing chamber 1, and electric fields and magnetic fields are introduced into the processing chamber 1 from the outside, the electrode 83 does not have to be arranged inside the processing chamber 1. Accordingly, it is possible to prevent metal contamination inside the processing chamber 1, so that a high-quality film can be deposited. However, because the case 90 is a dielectric material made of high-purity quartz, compared to a configuration in which the electrode 83 is inside the processing chamber 1, there are cases where it is difficult to cause plasma discharge. According to the plasma processing apparatus of an embodiment of the present invention, a plasma processing apparatus and a plasma processing method are provided that can stably cause plasma discharge while adopting a configuration in which the electrode 83 is provided outside the processing chamber 1.

The second plasma generation part 82 is provided between a position that is about 200 mm away from the central position of the wafer on the turntable 2 toward the periphery and a position that is about 90 mm away from the outer edge of the turntable 2 toward the periphery to be able to supply plasma to the wafer at the peripheral side in the radial direction of the turntable 2. In other words, when the turntable 2 rotates, the rotational speed is higher on the peripheral side than on the central side. Due to this, a quantity of plasma supplied to the wafer W is sometimes smaller on the outer peripheral side than on the inner peripheral side. Therefore, to supply the same quantity of plasma to the wafer W along the radial direction of the turntable 2, in other words, to compensate for the quantity of plasma supplied to the wafer W from the first plasma generation unit 80, the second plasma generation part 82 is provided.

The electrodes 83 included in the first plasma generation part 81 and the second plasma generation part 82, are separately connected to a high frequency power source 85 via a matching box 84. The high frequency power source 85 has a frequency of, for example, 13.56 MHz, and output power of, for example, 5000 W. Accordingly, the high frequency power can be separately adjusted for the first plasma generation part 81 and the second plasma generation part 82. Note that in FIG. 3, the matching boxes 84 and the high frequency power sources 85 are illustrated in a simplified manner. Furthermore, in FIGS. 1, 3, and 4, a connection electrode 86 is illustrated, for electrically connecting each of the first and second plasma generation parts 81 and 82 to the matching box 84 and the high frequency power source 85.

Here, the high frequency power source 85 is able to change the output (hereinafter, also simply referred to as “high frequency output”) of high frequency power supplied to the electrode 83. The output of the high frequency power source 85 is set at, for example, 3300 W, for a plasma process for regular film deposition in a processing room of 600° C. and at 1.8 Torr.

Next, a detailed description is given of the slits 97 of the Faraday shield 95. Among the electric field and magnetic field (electromagnetic field) generated in the first plasma generation part 81 and the second plasma generation part 82, the slits 97 prevent the electric field components from going toward the wafer W positioned below, and also causes the magnetic field to reach the wafer W. That is to say, if the electric field reaches the wafer, the electric wiring formed inside the wafer W may be electrically damaged. In the meanwhile, because the Faraday shield 95 is made of a grounded metal plate, unless slits 97 are formed, the electric field will be blocked as well as the magnetic field. Furthermore, if a large opening is formed at the bottom of the electrode 83, the magnetic field will pass therethrough as well as the electric field. Therefore, in order to block the electric field but let the magnetic field through, the slits 97 are formed having the following size and arrangement layout.

Specifically, as illustrated in FIG. 8, the slits 97 are formed at the bottom position of the electrode 83 across the circumferential direction, extending in a direction orthogonal to the winding direction of each of the electrodes 83 of the first plasma generation part 81 and the second plasma generation part 82. Accordingly, for example, in the area where the electrode 83 is arranged along the radial direction of the turntable 2, the slits 97 are formed in a linear shape or in an arc shape along the tangential direction or the circumferential direction of the turntable 2. Furthermore, in the area where the electrode 83 is placed in an arc shape along the outer edge of the turntable 2, the slits 97 are formed in a linear shape directed from the rotational center toward the outer edge of the turntable 2. Furthermore, at the part where the electrode 83 bends between the two areas, the slits 97 are formed in a tilted direction with respect to the circumferential direction and the radial direction of the turntable 2, so as to be orthogonal with respect to the direction in which the electrode 83 extends at the bending part. Accordingly, multiple slits 97 are arranged along the direction in which the electrode 83 extends.

Here, the high frequency power source 85 having a frequency of 13.56 MHz is connected to the electrode 83 as described above. The wavelength that corresponds to this frequency is 22 meters. Therefore, the slits 97 are formed to have a width that is approximately less than or equal to 1/10000 of this wavelength, i.e., as illustrated in FIG. 9, to have a width d1 of 1 mm through 5 mm (2 mm in this example), and have a space d2 between the slits 97 of 1 mm through 5 mm (2 mm in this example). Furthermore as illustrated in FIG. 8, the multiple slits 97 are formed in an area ranging from a position that is approximately 30 mm away from the right edge of the electrode 83 toward the right side, to a position that is approximately 30 mm away from the left edge of the electrode 83 toward the left side, such that the slits 97 are formed to have a length of 60 mm as viewed from the direction in which the electrode 83 extends. The area outside the area where the slits 97 are formed, i.e., on the center side of the area where the electrode 83 is wound around, openings 98 are formed in the Faraday shield 95 at the rotational center side and the outer peripheral side of the turntable 2. Note that in FIG. 3, the slits 97 are not illustrated. Furthermore, in FIGS. 4 and 5, the slits 97 are illustrated in a simplified manner, but, for example, actually about 150 slits 97 are formed. The slits 97 are actually formed such that the width d1 increases from the area in close contact with the opening 98 toward the area that is away from the opening 98, but, such a configuration of the slits 97 is not illustrated in the drawings.

Although only the first plasma generation unit 80 has been described in detail, the second plasma generation unit 130 and the case 140 can be configured as well as the first plasma generation unit 80 and the case 90. Hence, a description of the second plasma generation unit 130 is omitted.

Next, the description of the elements of the processing chamber 1 is continued. At a position that is slightly lower than the turntable 2 on the outer peripheral side of the turntable 2, as illustrated in FIGS. 2, 5, and 10, a side ring 100 that is a cover body is arranged. For example, the side ring 100 is used for protecting the inner walls of the processing chamber 1 from a cleaning gas, when the apparatus is cleaned and a fluoride-containing cleaning gas is circulated through the apparatus instead of processing gases. That is to say, unless the side ring 100 is provided, a recessed airflow passage in which an airflow (exhaust flow) is formed in the horizontal direction is formed in a ring shape along the circumferential direction between the outer peripheral part of the turntable 2 and the inner walls of the processing chamber 1. Therefore, the side ring 100 is provided in the airflow passage, such that the inner walls of the processing chamber 1 are exposed to the airflow passage as little as possible. In this example, the separation area D and the area on the outer edge side of the case 90 are exposed to the upper side of this side ring 100.

On the top surface of the side ring 100, exhaust openings 61, 62 are formed at two locations that are spaced apart from each other in the circumferential direction. In other words, two exhaust ports are formed on the lower side of the airflow passage, and the exhaust openings 61 and 62 are formed in the side ring 100 at positions corresponding to the exhaust ports of the airflow passage. Among these two exhaust openings 61 and 62, one is referred to as a first exhaust opening 61 and the other one is referred to as a second exhaust opening 62. The first exhaust opening 61 is formed at a position shifted toward the separation area D relative to the first plasma gas nozzle 31 between the first plasma gas nozzle 31 and the separation area D at the downstream side in the rotational direction of the turntable 2. The second exhaust opening 62 is formed at a position shifted toward the separation area D relative to the second plasma gas nozzle 32 between the second plasma gas nozzle 32 and the separation area D at the downstream side in the rotational direction of the turntable 2. The first exhaust opening 61 is for exhausting the first plasma gas for etching and the separation gas, and the second exhaust opening 62 is for exhausting the second plasma gas for modification and the separation gas. As illustrated in FIG. 1, the first exhaust opening 61 and the second exhaust opening 62 are connected to, for example, a vacuum pump 64, which is a vacuum exhaust mechanism, by an exhaust pipe 63 provided with a pressure adjustment unit 65 such as a butterfly valve.

Here, as described above, the cases 90 and 140 are provided from the central area C to the outer edge side of the turntable 2. Therefore, when various kinds of gases, which are discharged to the upstream side in the rotational direction of the turntable 2 with respect to the cases 90 and 140, the gas flows going toward the second exhaust openings 61 and 62 are regulated by the cases 90 and 140, respectively. Thus, gas flow paths 101 and 102 shaped as gaps through which the first and second plasma gas and the separation gas flow therethrough are formed in the top surface of the side ring 100 at the outside of the cases 90 and 140, respectively. Specifically, as illustrated in FIG. 3, the gas flow paths 101 and 102 are formed into an arc shape extending from a position closer to the first and second plasma gas nozzles 31 and 32 by, for example, approximately 60 mm, than the edge of the upstream side in the rotational direction of the turntable 2 of the cases 90 and 140, to the first and second exhaust openings 61 and 62, respectively, so as to have the depth of, for example, 30 mm. Accordingly, the gas flow paths 101 and 102 are formed so as to extend along the outer edges of the cases 90 and 140, and to cross the outer edge parts extending in the radial direction of the cases 90 and 140 as viewed from above. Although not illustrated, the surface of this side ring 100 is coated by, for example, alumina, or is covered by a quartz cover, for the purpose of applying a corrosion resistance property with respect to fluorinated gas.

As illustrated in FIG. 2, in the center part of the bottom surface of the ceiling plate 11, a protrusion part 5 is provided. Specifically, the protrusion part 5 is formed in a substantially ring shape along the circumferential direction in continuation with the part on the central area C side of the convex portion 4, and the bottom surface of the protrusion part 5 is formed to be at the same height as the bottom surface of the convex portion 4 (ceiling surface 44). Above the core part 21 closer to the rotational center side of the turntable 2 than the protrusion part 5, the labyrinth structure part 110 is arranged, which is for preventing the first plasma gas and the second plasma gas from mixing with each other at the central area C. That is to say, as illustrated in FIG. 1, the case 90 is formed up to a position close to the central area C side, and therefore in the core part 21 supporting the center part of the turntable 2, the part above the turntable 2 is formed at a position closer to the rotational center to avoid the case 90. Accordingly, for example, the different types of processing gases are more easily mixed with each other on the central area C side than on the outer edge side. Thus, by forming the labyrinth structure part 110, the gas flow path is extended and the different types of processing gases are prevented from being mixed with each other. In FIG. 1, although the case 140 is not illustrated, the case 140 has a structure similar to the case 90.

As illustrated in FIG. 1, in the space between the turntable 2 and the bottom part 14 of the processing chamber 1, a heater unit 7 that is a heating mechanism is provided. For example, the heater unit 7 heats the wafer W on the turntable 2 up to 300° C., through the turntable 2. FIG. 1 illustrates a cover member 71a provided on the side of the heater unit 7, and a hood member 7a covering the upper side of the heater unit 7. Furthermore, purge gas supply pipes 73 for purging the space where the heater unit 7 is arranged, are provided in the bottom part 14 of the processing chamber 1 below the heater unit 7 at a plurality of positions along the circumferential direction.

As illustrated in FIGS. 2 and 3, the transfer opening 15 is formed in the side wall of the processing chamber 1 for transferring wafers W, between an external transfer arm (not illustrated) and the turntable 2. This transfer opening 15 can be opened and closed in a gastight manner by a gate valve G. Furthermore, because wafers W are transferred between the transfer arm and the recessed portions 24 of the turntable 2 at the position facing the transfer opening 15, lift pins for lifting the wafer W from below through the recessed portions 24 and a lifting mechanism for the lift pins are provided (neither are illustrated) below the turntable 2 at the part corresponding to the position where the wafers W are transferred.

Moreover, as illustrated in FIG. 1, the etching apparatus is provided with a control unit 120 constituted by a computer for controlling the operations of the entire apparatus. The control unit 120 includes a CPU (Central Processing Unit) 121 and a memory 122. The memory 122 of the control unit 120 stores programs for performing an etching process and a modifying process described below. The CPU 121 reads these programs and executes the programs. These programs include a group of steps for executing operations of the apparatus described below, and the programs are installed in the memory 122 in the control unit 120 from a storage unit 125 that is a storage medium such as a hard disk, a compact disk, a magnetic optical disk, a memory card, and a flexible disk.

The control unit 120 controls the entire process control including a plasma process control according to a process recipe. Specific control and process contents of the plasma process control may be provided in a form of a conditioning recipe as well as the process recipe. For example, the process recipe and the conditioning recipe are installed from the storage unit 125 to the memory 122 in the control unit 120, and may be executed by the CPU 121.

Next, a description is given below of a plasma processing method according to an embodiment of the present invention. The plasma processing method of the present invention can be applied to a plasma processing apparatus other than the above-mentioned plasma processing apparatus as long as the plasma processing apparatus can periodically switch between an etching process and a modification process in a relatively short period of time. However, because the above-mentioned plasma processing apparatus can preferably perform the plasma processing method of the present invention, a description is given below of the plasma processing method according to the embodiment of the present invention by citing an example of using the above-mentioned plasma processing apparatus. Moreover, in the plasma processing method according to the embodiment of the present invention, a description is given below of an example of applying the plasma processing method of the present invention to an etching processing method.

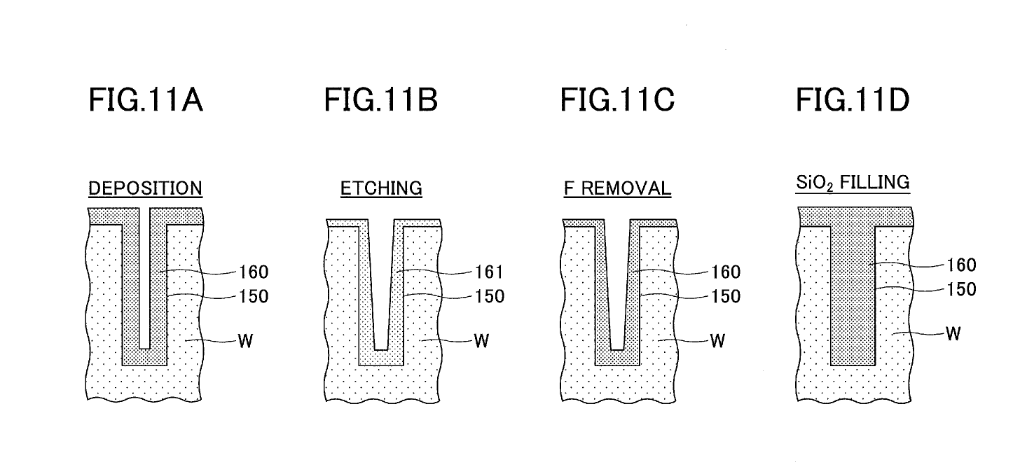

FIGS. 11A through 11D are a series of process drawings illustrating an example of the plasma processing method according to an embodiment of the present invention. FIG. 11A is a diagram illustrating an example of a plasma processing substrate preparation process. In the plasma processing substrate preparation process, a wafer W on which a film 160 to be etched is deposited is prepared. As illustrated in FIG. 11A, a recessed pattern 150 may be formed in a surface of the wafer W. The recessed pattern 150 is a wiring pattern including a recessed shape formed in the surface of the wafer W, and includes a groove shaped trench, a well-shaped hole having a high aspect ratio and the like. In the embodiment, a description is given below of an example of the film 160 being a SiO₂ film.

More specifically, to begin with, the gate valve G is opened (see FIGS. 2 and 3), and for example, five wafers W are placed on the turntable 2 by a transfer arm (not illustrated in the drawings) through the transfer opening 15 while rotating the turntable 2 intermittently. Next, the gate valve G is closed, and the processing chamber 1 is continued to be evacuated by the vacuum pump 64, and then the wafers W are heated by the heater unit 7 up to, for example, about 250 through 600° C. while rotating the turntable 2 in a clockwise fashion. Although the temperature of the wafers W is set at a variety of temperatures depending on the intended use, the temperature of the wafers W may be set at about 400° C. Also, although a pressure in the processing chamber 1 may be set at a variety of pressure values depending on the intended use, for example, the pressure may be set at 2 Torr.

Although the rotational speed of the turntable 2 varies depending on a process, for example, the rotational speed of the turntable 2 may be set in a rage of 1 to 240 rpm, or preferably in a range of 20 to 240 rpm.

Subsequently, the first plasma gas nozzle 31 supplies a mixed gas of Ar gas and NF₃ gas to the first plasma processing area P1, and the second plasma gas nozzle 32 supplies a mixed gas of Ar gas and H₂ gas to the second plasma processing area P2. Moreover, the separation gas nozzles 41 and 42 supplies Ar gas at a predetermined flow rate as a separation gas (or a purge gas), and the separation gas supply pipe 51 and the purge gas supply pipes 72 and 73 supply Ar gas at a predetermined flow rate. Then, the inside of the processing chamber 1 is adjusted to a preset processing pressure by the pressure adjustment unit 65. Furthermore, high frequency power is supplied to the first and second plasma generation units 80 and 130.

The flow rate of each of the gases may be set at a variety of flow rates depending on the intended use. For example, as a guide, a flow rate of Ar gas from the separation gas supply pipe 51 may be set at about 1 slm; a flow rate of Ar gas from the separation gas nozzles 41 and 42 may be set at about 5 slm; a flow rate of Ar gas from the first plasma gas nozzle 31 is set at 10 slm; flow rates of Ar gas and NF₃ gas from the second plasma gas nozzle 32 are set at about 10 slm and 0.1 slm, respectively; and flow rates of Ar gas and H₂ gas from the second plasma gas nozzle 32 may be set at about 10 slm and 2 slm, respectively.

FIG. 11B is a diagram illustrating an example of an etching process. The etching process is performed by rotating the turntable 2 and at the time the wafer W passes through the first plasma processing area P1. When the wafer W passes through the first plasma processing area P1, the film 160 is etched by plasma of Ar and F. Ar gas and NF₃ gas supplied from the first plasma gas nozzle 31 is converted into plasma by the first plasma generation unit 80, and the plasma etches the SiO₂ film 160. Even if the turntable 2 rotates at a relatively slow rotational speed, for example, of 20 rpm, because the turntable 2 requires just three seconds to rotate one revolution, the wafer W passes through the first plasma processing area P1 in a period shorter than 3 seconds. Hence, the etching process is performed on the film 160 in a short time that is shorter than three seconds. More exactly, because the first plasma processing area P1 has an area at most one fourth of the entire area of the turntable 2, the etching process is performed in a short time that is shorter than 0.75 seconds. In the etching process, because a fluoride component remains in the film 160, a state of the film 160 differs from a state illustrated in FIG. 11A, and the state illustrated in FIG. 11B is made a film 161.

FIG. 11C is a diagram illustrating an example of a modification process. The modification process is performed by rotating the turntable 2 and at the time the wafer W passes through the second plasma processing area P2 after passing through the separation area D. The wafer W is purged and cleaned by Ar gas that is the separation gas supplied from the separation gas nozzle 41 when passing through the separation area D. Then, after passing through the separation area D and when the wafer W passes through the second plasma processing area P2, the film 161 is modified by plasma of Ar and H. Ar gas and H₂ gas supplied from the second plasma gas nozzle 32 is converted into plasma by the second plasma generation unit 130, and the plasma reacts with the fluoride component in the SiO₂ film and releases from the SiO₂ film by becoming HF, thereby reducing the F component in the SiO₂ film 161. The reaction on this occasion is expressed in the following chemical formula (2).

H+HF→HF (2)

As described in FIG. 11B, even if the turntable 2 rotates at a relatively slow rotational speed of, for example, 20 rpm, because one revolution is finished in three seconds, the wafer W passes through the second plasma processing area P2 in a period shorter than three seconds. Hence, the modification process for less than three seconds is performed on the film 160. More exactly, because the second processing area P2 has an area at most one fourth of the entire area of the turntable 2, the modification process is performed in a short time of less than 0.75 seconds. Here, because the fluoride component disappears or decreases in the film 161 in the modification process, the quality of film 161 returns to a state similar to the state illustrated in FIG. 11A. This state of the film in which the film quality has been recovered is hereinafter expressed as the film 160 that is the same as the film 160 in FIG. 11A.

The wafer W passes the separation area D located on the downstream side of the second plasma processing area P2 in the rotational direction of the turntable 2 after passing the second plasma processing area P2, and is purged and cleaned by receiving the supply of Ar gas from the separation gas nozzle 42. Then, the wafer W has passed the separation area D.

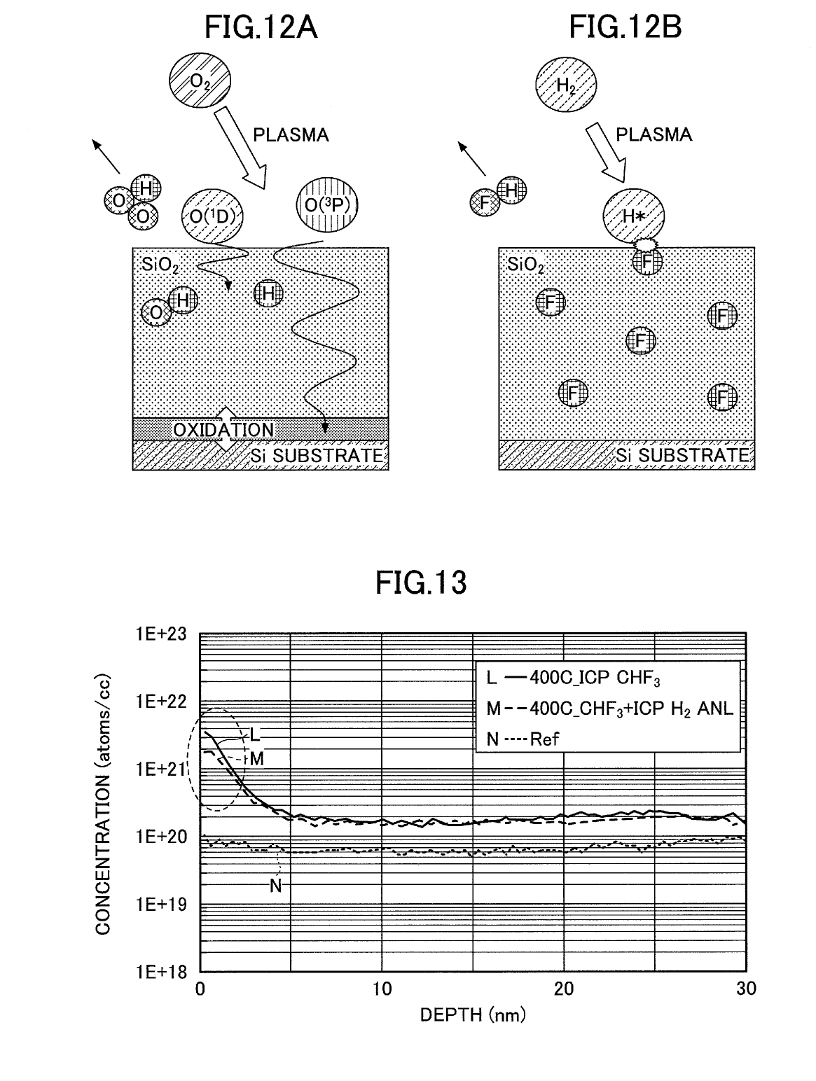

Here, because the turntable 2 continuously keeps rotating, the etching process illustrated in FIG. 11B and the modification process illustrated in FIG. 11C are repeated in the same period until the turntable 2 stops. The cycle becomes three seconds even when the rotational speed is 20 rpm that is relatively slow. When the rotational speed is 240 rpm that is fast, the cycle is 0.25 seconds. The cycle is, for example, in a range of 0 to 60 seconds, preferably in a range of 0 to 30 seconds, further preferably in a range of 0.25 to 3 seconds. Hence, by rotating the turntable 2, a cycle constituted of an etching process, a purge process, a modification process and a purge process in a very short time, are repeated a plurality of times in the same period. Naturally, the quantity of etching and the quantity of modification become an atomic layer level, and an etching process by ALE (atomic layer etching) and a modification process after the etching is performed alternately and periodically. Repeating such a very small quantity of etching process and a very small quantity of modification process is very effective to form a high-quality etching film having a low fluoride content. In general, in a conventional etching process, different from the etching process according to the embodiment, the etching process illustrated in FIG. 11B has been continuously performed for a certain amount of long time, and the modification process illustrated in FIG. 11C has been continuously performed for a certain amount of long time. However, in this case, the fluoride component has not been often able to be reduced sufficiently due to an insufficient modification process. In the plasma processing method of the embodiment, the fluoride component in the film 160 can be efficiently removed. In this regard, a detailed description is given below with reference to FIGS. 12A and 12B.

FIGS. 12A and 12B are diagrams for explaining the modification process of the plasma processing method according to the embodiment. FIG. 12A is a diagram for explaining an O₂ plasma modification process performed during a film deposition of a SiO₂ film. As illustrated in FIG. 12A, when the SiO₂ film is deposited, in general, a modification process by an oxidation gas such as O₂ gas, O₃ gas or the like. O₂ gas is converted into plasma, and O(³P) reaches the inside of the SiO₂ film and can oxidize a Si substrate. Moreover, although O (¹P) has a short life time and cannot reach a deep location in the film, because the reactivity is very high, modifying a surface of the SiO₂ film is possible. In other words, during the film deposition of the SiO₂ film, by performing the O₂ plasma modification process for a certain amount of time after depositing the SiO₂ film up to a predetermined film thickness, the modification process by oxidation can be performed to the inside of the film.

FIG. 12B is a diagram for explaining an H₂ plasma modification process performed while etching the SiO₂ film. As illustrated in FIG. 12B, when etching the SiO₂ film, in general, the modification process by H₂ gas is performed. Although H₂ plasma has a high reactivity, because the life time is short, the H₂ plasma does not reach a deep location inside the film, and a modification reaction inevitably occurs at a surface of the film. Due to this, even if the etching process is performed for a long time until etching up to a predetermined quantity of etching and then the modification process of the film is tried to be performed on the etched film all at once, the H plasma does not reach the inside of the film, which makes it difficult to remove the fluoride component. Accordingly, the plasma processing method of the embodiment of performing a small quantity of modification process after performing a small quantity of etching is very effective to remove the fluoride component from the film, which makes it possible to efficiently remove or reduce the fluoride component in the SiO₂ film.

FIG. 13 is a graph showing analysis results of a fluoride concentration in a SiO₂ film after performing a conventional modification process. In FIG. 13, a residual fluoride concentration in a film without being subject to an etching process is expressed by a curve N; a residual fluoride concentration in a film subject to an etching process and a modification process is expressed by a curve M; and a residual fluoride concentration in a film being only subject to an etching process without an modification process is expressed by a curve L under conditions in which a temperature is the processing chamber 1 is 400° C.; a rotational speed of the turntable 2 is 60 rpm; an output of the high frequency power source is 1500 W: a flow rate of Ar gas is 10 kcc; a flow rate of an etching gas is 50 cc.

As illustrated in FIG. 13, the curves L and M subject to the etching both have residual fluoride concentrations much higher than the residual fluoride concentration of the curve N. The fluoride concentration of the curve M subject to the modification process is lower than the fluoride concentration of the curve L in an area that is shallower than 3 nm from the surface, which is a shallow area of the film, and the slight effect of reducing the fluoride concentration can be found. However, the effect is small, and the effect of reducing the fluoride concentration can be hardly found in an area equal to or deeper than 5 nm of the film. In this regard, the results agree with the contents described in FIGS. 12A and 12B.

A description is given below with reference to FIGS. 11A through 11D again. As described in FIGS. 11B and 11C, by repeating the small quantity of etching process and the modification process for removing the small quantity of fluoride at the surface, the problem of the conventional technique described in FIGS. 12A, 12B and 13 can be solved, and a SiO₂ film containing a low fluoride component can be formed.

FIG. 11D is a diagram illustrating an example of a filling process. In the filling process, after finishing desired etching process and modification process, filling a recessed pattern 150 is performed as necessary. Because the etching process and the modification process have finished in FIGS. 11B and 11C, the process illustrated in FIG. 11D does not have to be performed when the plasma processing method includes only the etching process. In contrast, by repeating the film deposition illustrated in FIGS. 11A through 11C and the etching process, the recessed pattern 150 may be gradually filled. The plasma processing method of the embodiment can be applied to a variety of processes including the etching process.

After finishing the substrate process including the etching, the wafer W is carried out of the processing chamber 1 in a reverse manner to carrying the wafer W into the processing chamber 1, and a predetermined substrate process finishes.

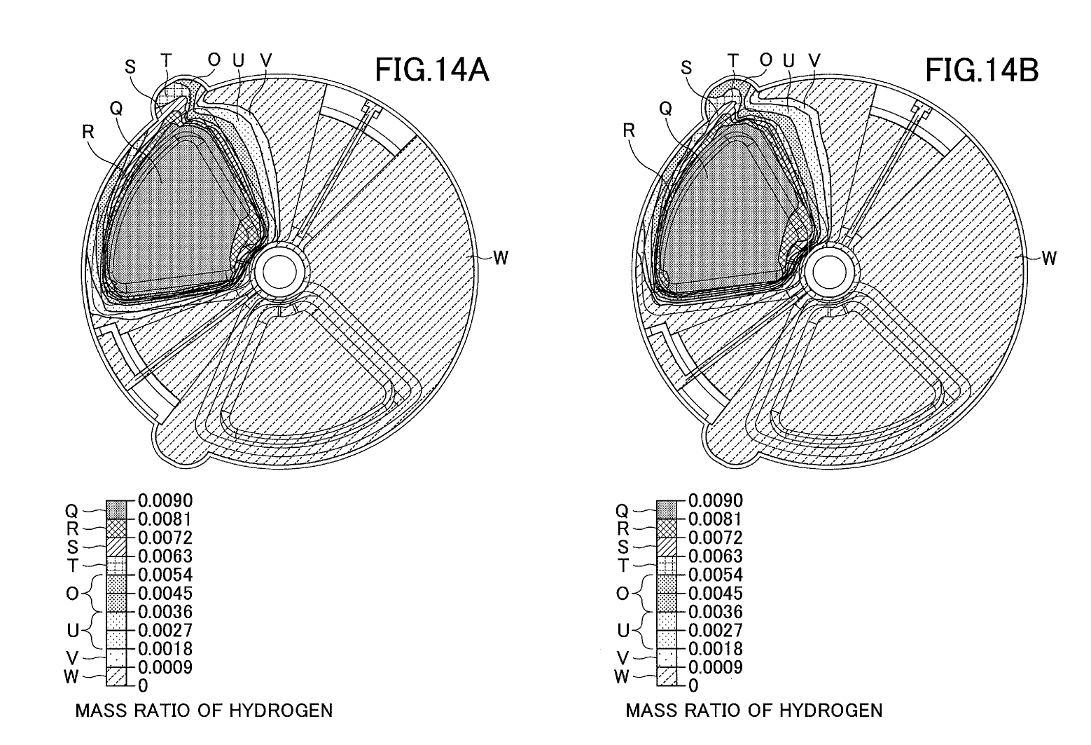

FIGS. 14A and 14B are diagrams showing simulation results indicating an isolation state of hydrogen gas in the plasma processing apparatus of the embodiment. FIG. 14A is a diagram showing an isolation state of hydrogen gas when the rotational speed of the turntable 2 is set at 20 rpm, and FIG. 14B is a diagram showing an isolation state of hydrogen gas when the rotational speed of the turntable 2 is set at 240 rpm.

As discussed above, NF₃ gas of an etching gas and H₂ gas of a modification gas cause an explosion when being mixed in a predetermined concentration range, and even if the explosion is not caused, if HF is produced, HF adversely affects the inner wall of the processing chamber 1. Hence, NF₃ gas and H₂ gas are preferred to be completely isolated from each other. Accordingly, in order to understand an isolation status of a modification gas and an etching gas while the plasma processing apparatus of the embodiment performs the plasma processing method of the embodiment, simulation experiments was performed.

FIGS. 14A and 14B illustrate mass concentrations of H₂ gas of a modification gas. The simulation conditions is as follows: a pressure in the processing chamber 1 is 2 Torr; a temperature of a wafer W is 400° C.; a flow rate of Ar gas from the separation gas supply pipe 51 is 1 slm; a flow rate of Ar gas from the separation gas nozzles 41 and 42 is 5 slm; flow rates of Ar gas and NF₃ gas from the first plasma gas nozzle 31 are 10 slm and 0.1 slm, respectively; and flow rates of Ar gas and H₂ gas from the second plasma gas nozzle 32 are 10 slm and 2 slm, respectively.

As illustrated in FIGS, 14A and 14B, in both cases of the rotational speed of the turntable 2 being 20 rpm and 240 rpm, areas Q and R where the mass ratio of hydrogen are high almost match the second plasma processing area P2. Although areas S, T and O having middle degrees of mass ratio of hydrogen and areas U and V having low degrees of mass ratio of hydrogen slightly run out downstream of the second plasma processing area P2 in the rotational direction of the turntable 2 by being pulled by the rotation of the turntable 2, the other is an area W having a mass ratio of hydrogen of approximately zero. Here, the area having high mass ratios of hydrogen is larger in FIG. 14B of higher rotational speed of the turntable 2 than in FIG. 14A of lower rotational speed of the turntable 2, but the area V does not still reach the separation area D. Accordingly, the results indicate that an isolation capability of hydrogen gas in the second plasma processing area P2 and one in the separation area D are sufficiently high, and that there is no problem about the isolation of hydrogen gas.

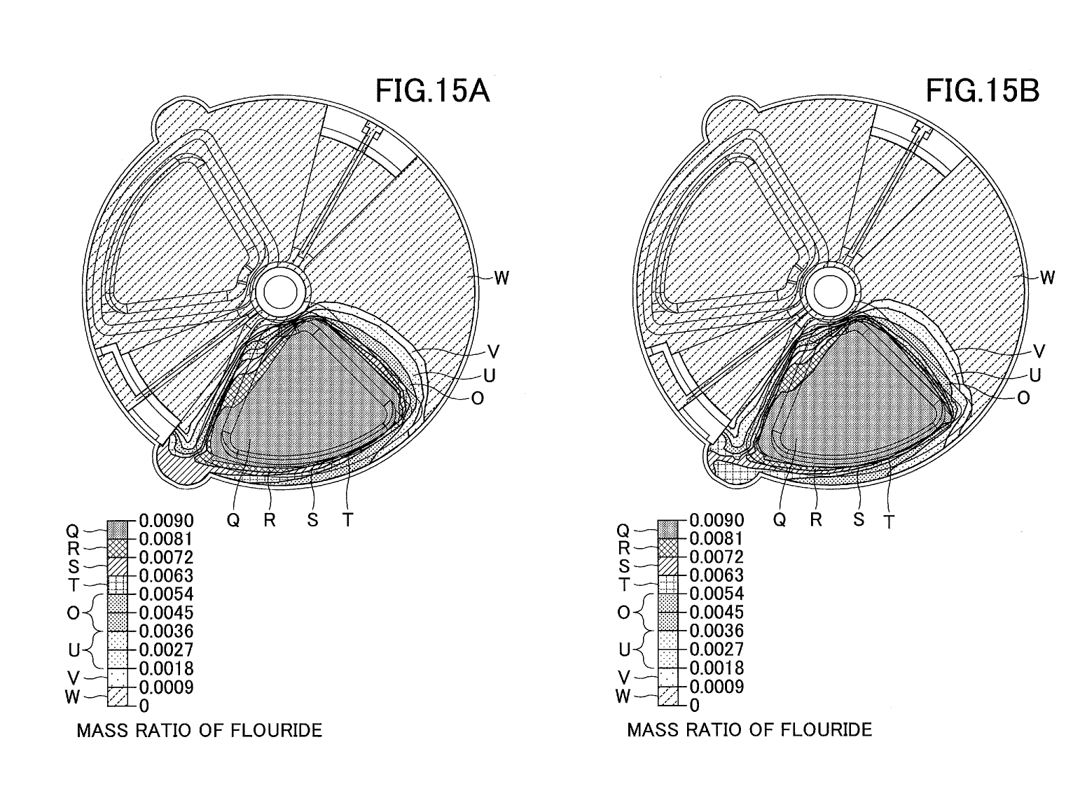

FIGS. 15A and 15B are diagrams showing simulation results indicating an isolation state of NF₃ gas in the plasma processing apparatus of the embodiment. FIG. 15A is a diagram showing an isolation state of NF₃ gas when the rotational speed of the turntable 2 is set at 20 rpm, and FIG. 15B is a diagram showing an isolation state of NF₃ gas when the rotational speed of the turntable 2 is set at 240 rpm.

The simulation conditions are the same as the conditions described in FIGS. 14A and 14B. In FIGS. 15A and 15B, areas Q and R having high mass ratio of NF₃ gas stay in the vicinity of the first plasma processing area P1. Although areas S, T and O having middle mass ratios of fluoride and areas U and V having low mass ratio of fluoride slightly go beyond the first plasma processing area P1 on both sides in the rotational direction of the turntable 2, fluoride is completely isolated by the separation area D located downstream of the first plasma processing area P1 in the rotational direction of the turntable 2, and the separation area D and an area downstream of the separation area are in an area W having a mass ratio of fluoride of approximately zero. On the upstream side, even a location that does not reach the separation area D far therefrom is in an area W having the mass ratio of fluoride of approximately zero. Naturally, the mass ratio of fluoride is approximately zero in an area including the second plasma processing area P2 and sandwiched between the separation areas D (area W). Accordingly, the results indicate that an isolation capability of NF₃ gas of the first plasma processing area P1 and an isolation capability of NF₃ gas of the separation areas D are sufficiently high, and that there is no problem about the isolation of NF₃ gas.

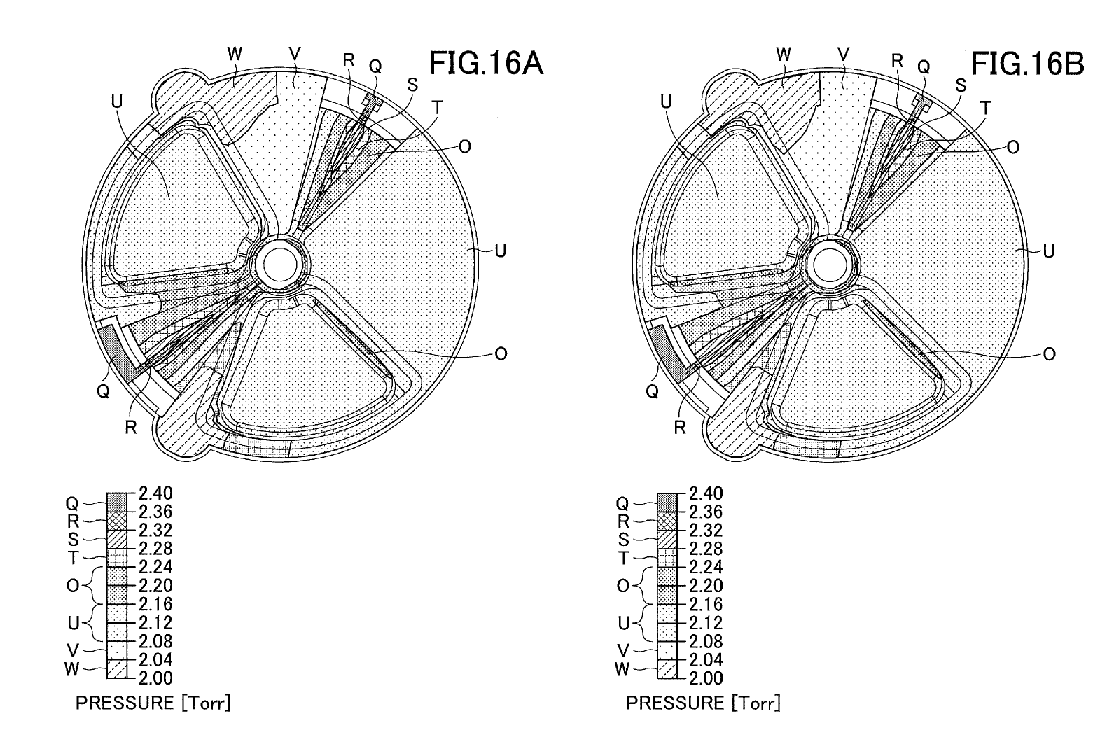

FIGS. 16A and 16B are diagrams showing simulation results indicating an isolation state of a separation gas in the plasma processing apparatus of the embodiment in terms of a pressure. FIG. 16A is a diagram showing a pressure state in the processing chamber 1 when the rotational speed of the turntable 2 is set at 20 rpm, and FIG. 15B is a diagram showing a pressure state in the processing chamber 1 when the rotational speed of the turntable 2 is set at 240 rpm.

The simulation conditions are the same as the conditions described in FIGS. 14A and 14B. Hence, the pressure in the processing chamber 1 is set at 2 Torr. As illustrated in FIGS. 16A and 16B, although the pressure of the separation gas nozzles 41 and 42 and the surroundings thereof are included in areas Q, R, S and T having high pressures, the other area is included in areas U and V having a middle pressure and a slightly low pressure, respectively. This indicates that the pressures of the separation gas nozzles 41 and 42 and the surroundings thereof are higher than the other area and that there is no problem about a gas isolation capability of the separation areas D. Therefore, the results indicated that the separation areas D do not have any problem about the gas isolation capability in terms of the pressure.

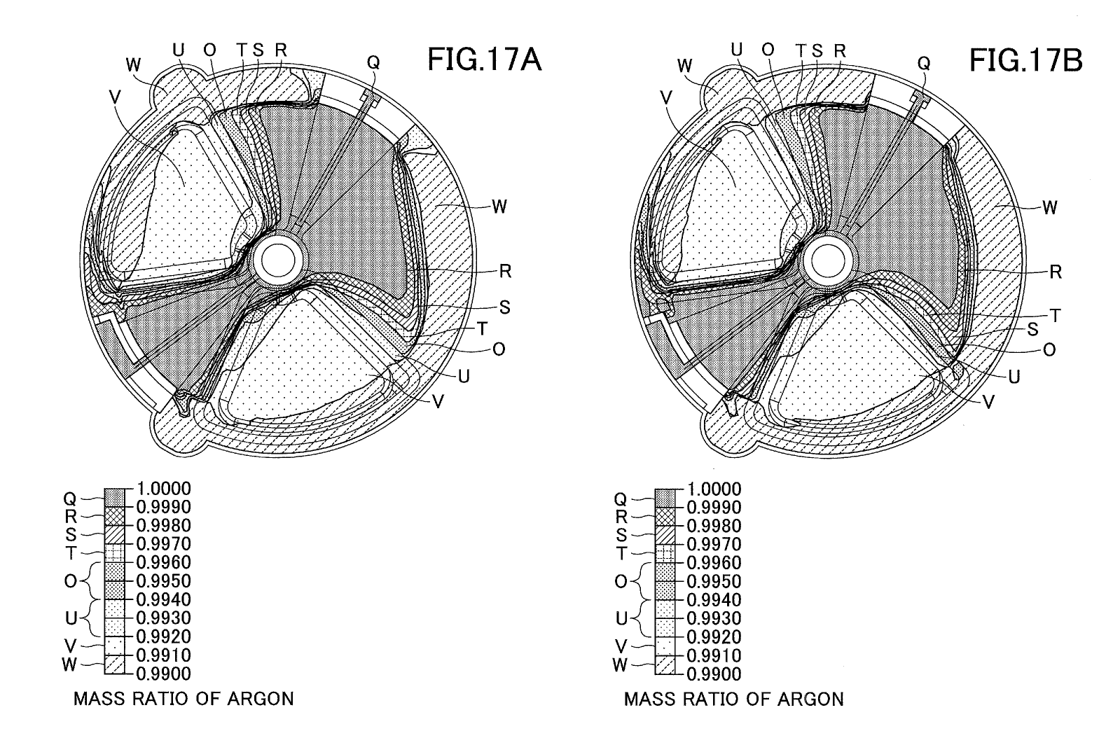

FIGS. 17A and 17B are diagrams showing simulation results indicating an isolation state of a separation gas in the plasma processing apparatus of the embodiment in terms of amass concentration of Ar. FIG. 17A is a diagram showing a mass concentration of Ar in the processing chamber 1 when the rotational speed of the turntable 2 is set at 20 rpm, and FIG. 17B is a diagram showing a mass concentration of Ar in the processing chamber 1 when the rotational speed of the turntable 2 is set at 240 rpm.

As illustrated in FIGS. 17A and 17B, while an area Q having a high mass concentration of Ar dominates areas other than the separation areas D and the first and second plasma processing areas P1 and P2, an area V having a low mass concentration of Ar dominates the areas in the first and second plasma processing areas P1 and P2. This indicates that there is no problem about a gas isolation capability by Ar gas supplied from the separation gas areas D as a purge gas. In other words, the gas concentration of Ar gas differs in area, which shows the high gas isolation capability. Accordingly, the results indicate that the separation areas D do not have any problem about the gas isolation capability in terms of the mass concentration of Ar.

In this manner, the plasma processing apparatus of the embodiments has a high gas isolation capability. Thus, H₂ gas and NF₃ gas that can cause a problem when being mixed with each other can be supplied into the processing chamber 1 at the same time, and a fluoride component in a film can be efficiently removed or reduced by periodically performing ALE and a small quantity of modification process. This allows a film to be etched while keeping a film quality high.

Although the plasma processing apparatus and the plasma processing method according to the embodiments have been described by citing an example of performing an etching process on a SiO₂ film, the etching process can be performed on a variety of films including a SiN film and a TiN film.

Moreover, in addition to the etching process, as long as a process needs two different types of plasma processes, the plasma processing apparatus and the plasma processing method of the embodiment can be preferably applied to the process. For example, the plasma processing apparatus and the plasma processing method of the embodiment can be applied to a variety of processes such as a film deposition process, a process of filling a recessed pattern with a film by performing both of a film deposition process and an etching process alternately and the like.

According to the embodiments of the present invention, an etching can be performed while reducing a fluoride concentration in a film.

All examples and conditional language recited herein are intended for pedagogical purposes to aid the reader in understanding the embodiments and the concepts contributed by the inventor to furthering the art, and are to be construed as being without limitation to such specifically recited examples and conditions, nor does the organization of such examples in the specification relate to a showing of superiority or inferiority of the embodiments. Although the method of manufacturing the silicon oxide film has been described in detail, it should be understood that the various changes, substitutions, and alterations could be made hereto without departing from the spirit and scope of the invention.

What is claimed is:

1. A plasma processing apparatus comprising:
a processing chamber;
a turntable to receive a substrate thereon provided in the processing chamber;
a first plasma processing area provided in a predetermined location in a circumferential direction of the turntable and configured to perform a first plasma process by generating first plasma from a first plasma gas;
a second plasma processing area provided apart from the first plasma processing area in the circumferential direction of the turntable and configured to perform a second plasma process by generating second plasma from a second plasma gas; and
a separation area provided in each of two locations between the first plasma processing area and the second plasma processing area and configured to prevent the first plasma gas and the second plasma gas from mixing with each other by separating the first plasma processing area from the second plasma processing area.

2. The plasma processing apparatus as claimed in claim 1,
wherein the first plasma processing area includes a first plasma gas nozzle to supply the first plasma gas,
wherein the second plasma processing area includes a second plasma gas nozzle to supply the second plasma gas, and
wherein the separation area includes a separation gas nozzle.

3. The plasma processing apparatus as claimed in claim 1,
wherein the first plasma processing area is an area configured to perform an etching process, and
the second plasma processing area is an area configured to perform a modification process after the etching process.

4. The plasma processing apparatus as claimed in claim 1, wherein the first plasma processing area and the second plasma processing area include side walls protruding from a ceiling surface of the processing chamber toward the turntable provided to prevent the first plasma gas and the second plasma gas from flowing out of the first plasma processing area and the second plasma processing area, respectively.

5. The plasma processing apparatus as claimed in claim 2, wherein the separation area includes a convex portion protruding from a ceiling surface of the processing chamber toward the turntable so as to form a narrow space between a lower surface thereof and an upper surface of the turntable, and a groove provided in the convex portion and having a surface higher than the lower surface of the convex portion to accommodate the separation gas nozzle therein, and prevents the first plasma gas and the second plasma gas from mixing with each other by supplying the separation gas from the separation gas nozzle.

6. The plasma processing apparatus as claimed in claim 1,
wherein a fluoride-containing gas is supplied to the first plasma processing area as the first plasma gas,
wherein a hydrogen-containing gas is supplied to the second plasma processing area as the second plasma gas, and
wherein a noble gas or nitrogen gas is supplied to the separation area.

7. The plasma processing apparatus as claimed in claim 1, wherein an area divided by the separation area in the circumferential direction includes exhaust openings in a bottom surface of the processing chamber.

8. The plasma processing apparatus as claimed in claim 7, wherein the exhaust openings are provided downstream of the first plasma processing area and the second plasma processing area in a rotational direction of the turntable, respectively.

9. The plasma processing apparatus as claimed in claim 1, wherein the turntable is rotatable in a direction that causes the substrate received thereon to pass in the following order of the first plasma processing area, a first separation area, the second plasma processing area, and a second separation area.

10. A plasma processing method, comprising steps of:
performing a first plasma process on a substrate by generating first plasma from a first plasma gas;
purging the substrate subject to the first plasma process by a first purge gas;
performing a second plasma process on the purged substrate by generating second plasma from a second plasma gas;
purging the substrate subject to the second plasma process by a second purge gas; and
performing two types of plasma processes constituted of the first plasma process and the second plasma process alternately by repeating a cycle constituted of steps of performing the first plasma process, purging the substrate subject to the first plasma process, performing the second plasma process and purging the substrate subject to the second plasma process a plurality of times in a constant period.

11. The plasma processing method as claimed in claim 10,
wherein the first plasma process is an etching process, and
wherein the second plasma process is a modification process after the etching process.

12. The plasma processing method as claimed in claim 11,
wherein a film is deposited on a surface of the substrate,
wherein the etching process is a process of etching the film deposited on the substrate, and
wherein the modification process is a process of modifying the etched film.

13. The plasma processing method as claimed in claim 12,
wherein the etching process is a process of etching the film at a molecular layer level, and
wherein the modification process is a process of modifying a surface of the etched film at a molecular layer level.

14. The plasma processing method as claimed in claim 11,
wherein the first plasma gas is a fluoride-containing gas,
wherein the second plasma gas is a hydrogen-containing gas, and
wherein the purge gas is a noble gas or nitrogen gas.

15. The plasma processing method as claimed in claim 10, wherein a period of time required for the cycle is longer than zero seconds and equal to or shorter than 30 seconds.

16. The plasma processing method as claimed in claim 15, wherein the period of time required for the cycle is equal to or longer than 0.25 seconds and equal to or shorter than 12 seconds.

17. The plasma processing method as claimed in claim 10, further comprising steps of:
placing a plurality of substrates on a turntable provided in a processing chamber along a circumferential direction of the turntable,
wherein the processing chamber includes a first plasma processing area to perform the first plasma process, a first purge area to purge the substrate subject to the first plasma process by the purge gas, a second plasma processing area to perform the second plasma process, and a second purge area to purge the substrate subject to the second plasma process arranged along a rotational direction of the turntable in this order, and the step of performing two of the types of plasma processes is performed by rotating the turntable at a predetermined rotational speed.

18. The plasma processing method as claimed in claim 17,
wherein the first plasma processing area is separated from the second plasma processing area by the first and second purge areas,
wherein the step of purging the substrate subject to the first plasma process by the purge gas prevents the second plasma gas from mixing into the first plasma processing area during the step of performing the first plasma process, and
wherein the step of purging the substrate subject to the second plasma process by the purge gas prevents the first plasma gas mixing into the second plasma processing area during the step of performing the second plasma process.
